(19) United States
(12) Patent Application Publication
(10) Pub. No.: US 2021/0161014 A1
(43) Pub. Date: May 27, 2021

(54) Circuit Board Assembly, Display Panel and Display Device

(71) Applicants: HKC Corporation Limited, Shenzhen, Guangdong (CN); Chongqing HKC Optoelectronics Technology Co., Ltd., Chongqing (CN)

(72) Inventor: Zhi Xiong, Shenzhen, Guangdong (CN)

(21) Appl. No.: 16/313,461

(22) PCT Filed: Oct. 25, 2018
(86) PCT No.: PCT/CN2018/111827

§ 371 Date: Dec. 26, 2018

(30) Foreign Application Priority Data
Aug. 27, 2018 (CN) 201810992016.3

(51) Int. Cl. H05K 1/18; G09G 3/20

(52) U.S. Cl. CPC H05K 1/181; G09G 3/20; G09G 2310/08; G06F 1/183; G09G 2320/0673; H05K 2201/10128; G09G 2330/021

(57) ABSTRACT

The present disclosure discloses a circuit board assembly, a display panel and a display device. The circuit board assembly includes a circuit board body, which includes a first side surface and a second side surface. The first side surface faces away from the second side surface, the first side surface defines a bonding area, the second side surface defines a mounting area, and the mounting area defines a mounting site for mounting a functional chip.

### FIELD

The present disclosure relates to the field of display manufacturing, and in particular, relates to a circuit board assembly, a display panel, and a display device.

### BACKGROUND

With the development of science and technology, people's demand on display panel design is higher and higher. A display panel is generally formed by connecting a circuit board, a data driving chip and a display screen via bonding technology. In the display panels in prior art, a functional chip is defined on a circuit board, and the functional chip and a bonding area are defined on the same side of the circuit board. Due to the limited length of the circuit board, in order to effectively install the functional chip, the width of the circuit board may be increased, thus affecting the thinning of the display panel as a whole.

### SUMMARY

The main purpose of the disclosure is to provide a circuit board assembly, aiming at solving the technical problem of how to improve the thinning effect of the overall display panel.

In order to achieve the above object, the circuit board assembly proposed in this disclosure includes:

a circuit board body, including a first side surface and a second side surface, and the first side surface faces away from the second side surface, the first side surface defines a bonding area, the second side surface defines a mounting area, and the mounting area defines a mounting site for mounting a functional chip.

Alternatively, the projection of the mounting area on the first side at least partially overlaps with the bonding area.

Alternatively, the width of the overlap between the projection of the mounting area on the first side and the bonding area is 0 mm to 2 mm.

Alternatively, the amount of the bonding areas is plural, and the plural bonding areas are defined at intervals along a long side of the circuit board body.

Alternatively, the amount of the mounting sites is a plurality, and the plurality of the mounting sites are defined at intervals along the length direction of the mounting area.

Alternatively, the circuit board assembly further includes a functional chip mounted on the mounting site.

Alternatively, the functional chip is soldered to the mounting site.

Alternatively, the functional chip includes at least one selected from a group consisting of a timing control chip, a power chip, and a programmable gamma chip.

The disclosure also provides a display panel, including a circuit board assembly, and the circuit board assembly comprises: a circuit board body, including a first side and a second side, the first side facing away from the second side, the first side defining a bonding area, the second side defining a mounting area, the mounting area defining a mounting site for mounting a functional chip.

The disclosure also provides a display device including a display panel, the display panel includes a circuit board assembly, and the circuit board assembly comprises: a circuit board body, including a first side and a second side, the first side facing away from the second side, the first side defining a bonding area, the second side defining a mounting area, the mounting area defining a mounting site for mounting a functional chip.

According to the circuit board assembly disclosed by the disclosure, the bonding area and the mounting area of a functional chip are respectively defined on a first side surface and a second side surface facing away from the first side surface of the circuit board body, so that the bonding area and the mounting area do not interfere with each other, and thus the spacing distance between the bonding area and the mounting area is reduced at least, thereby reducing the overall width of the circuit board body, improving the thinning effect of the display panel as a whole and reducing the production and processing cost of the circuit board body.

### BRIEF DESCRIPTION OF THE DRAWINGS

In order to more clearly explain the embodiments of the present disclosure or the technical solutions in the prior art, the drawings that need to be used in the embodiments or the description of the prior art will be briefly introduced below. obviously, the drawings in the following description are only some embodiments of the present disclosure. for those of ordinary skill in the art, other drawings can be obtained according to the structures shown in these drawings without paying creative labor.

FIG. 1 is a schematic diagram of the structure of a circuit board assembly in an embodiment of the present disclosure;

FIG. 2 is a schematic diagram of the structure of a circuit board assembly in another embodiment of the present disclosure;

FIG. 3 is a schematic diagram of the structure of a display panel in an embodiment of the present disclosure.

### BRIEF DESCRIPTION OF THE DRAWINGS

| Label | Name | Label | Name | Label | Name |
|---|---|---|---|---|---|
| 10 | Circuit board | 11 | First side | 12 | Second side |
| | body | | | | |
| 111 | Bonding region | 121 | Mounting area | 13 | Functional chip |
| 20 | Display screen | 21 | driving chip | | |

The realization, functional features and advantages of the purpose of this disclosure will be further described with reference to the accompanying drawings in conjunction with the embodiments.

### DETAILED DESCRIPTION OF THE EMBODIMENTS

The technical schemes of the embodiments of the present disclosure will be clearly and fully described in the following with reference to the accompanying drawings. It is obvious that the embodiments to be described are only a part rather than all of the embodiments of the present disclosure. Based on the embodiments in this disclosure, all other embodiments obtained by a person of ordinary skill in the art without creative labor are within the scope of protection of this disclosure.

It should be noted that if the embodiments of the present disclosure involve directional indications (such as up, down, left, right, front, back, etc.), the directional indications are only used for explaining the relative positional relationship and movement between the components in a certain posture (as shown in the drawings), and if the specific posture changes, the directional indications will change accordingly.

In addition, if the embodiments of the present disclosure involve descriptions of “first” and “second”, the descriptions of “first” and “second” are for descriptive purposes only and cannot be understood as indicating or implying their relative importance or implicitly indicating the amount of indicated technical features. Thus, features defining “first” and “second” may explicitly or implicitly include at least one such feature. In addition, the meaning of “and/or” appearing in the full text is to include three parallel schemes, taking “A and/or B as an example”, it means including scheme A or scheme B, or a scheme that both A and B satisfy. In addition, the technical solutions between the various embodiments may be combined with each other, but must be based on what one of ordinary skill in the art can achieve. When the combination of technical solutions is contradictory or impossible to achieve, it should be considered that the combination of such technical solutions does not exist and is not within the scope of protection required by this disclosure.

The disclosure provides a circuit board assembly.

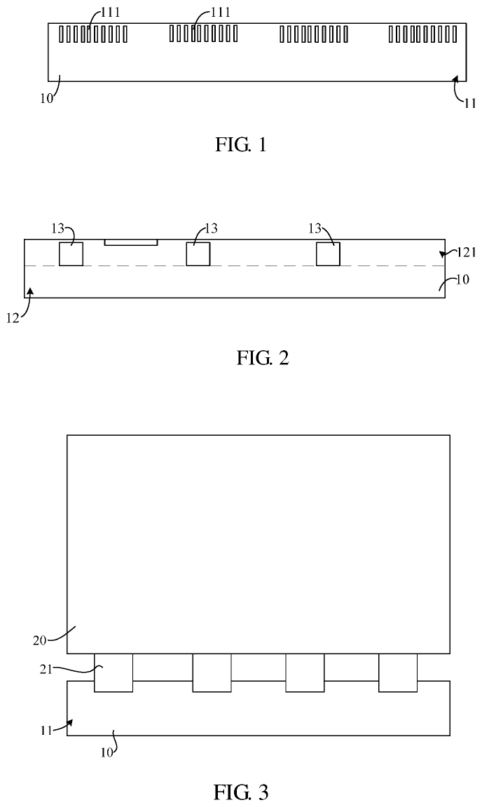

In embodiments of the present disclosure, as shown in FIGS. 1 and 2, the circuit board assembly includes:

a circuit board body 10, including a first side surface 11 and a second side surface 12, the first side surface 11 faces away from the second side surface 12, the first side surface 11 having a bonding area 111, and the second side surface 12 having a mounting area 121, the mounting having a mounting site for mounting the functional chip 13.

In this embodiment, the bonding area 111 is generally adjacent to a side of the circuit board body 10, and a bonding mark is defined in the bonding area 111 for bonding a driving chip 21 of the display panel to the circuit board, and the driving chip 21 may be bonded to the bonding mark in bonding process. The mounting area 121 is configured for mounting the functional chip 13, and the mounting area 121 is defined with a mounting site, to which the functional chip 13 may be soldered when processing the display panel. The first side surface 11 and the second side surface 12 are two sides of the circuit board, and the first side surface 11 faces away from the second side surface 12. It may be noted that the first side surface 11 and the second side surface 12 do not correspond to the front and back surfaces of the display panel, but only need to satisfy that the bonding area 111 and the mounting area 121 are defined on different sides of the circuit board body 10. The circuit board body 10 is generally in a strip shape with one long side opposite to one side of the display screen 20. The bonding area 111 and the mounting area 121 both occupy a certain width of the circuit board body 10. Therefore, defining the bonding area 111 and the mounting area 121 on different sides of the circuit board body 10 is beneficial to reducing the overall width of the circuit board body 10.

According to the circuit board assembly of the present disclosure, the bonding area 111 and the mounting area 121 of the functional chip 13 are respectively defined on the first side 11 and the second side 12 facing away from the first side 11 of the circuit board body 10, so that the bonding area 111 and the mounting area 121 do not interfere with each other, and thus the spacing distance between the bonding area 111 and the mounting area 121 is reduced at least, thereby reducing the overall width of the circuit board body 10, improving the thinning effect of the display panel as a whole, reducing the production and processing costs of the circuit board body 10 and improving the utilization rate of both sides of the circuit board body 10.

Further, as shown in FIGS. 1 and 2, the projection of the mounting area 121 on the first side 11 at least partially overlaps with the bonding area 111. In this embodiment, the projection of the mounting area 121 on the first side 11 at least partially overlaps with the bonding area 111, reducing the area occupied by the mounting area 121 on the second side 12 of the circuit board body 10, thereby further reducing the width of the circuit board body 10 and improving the overall utilization rate of the circuit board body 10.

Further, as shown in FIGS. 1 and 2, the width of the overlap between the projection of the mounting area 121 on the first side 11 and the bonding area 111 is 0 mm to 2 mm. In this embodiment, if the projection of the mounting area 121 on the first side 11 partially overlaps with the bonding area 111, the width of the circuit board body 10 may be reduced by at least the width of the overlapped portion, while the width of the mounting area 121 is generally larger than the bonding area 111. Therefore, if the projection of the mounting area 121 on the first side 11 completely overlaps with the bonding area 111, the width that the circuit board body 10 may be reduced by at least the total width of the bonding area 111. In practical application, the width of the bonding area 111 is generally 2 mm. Therefore, if the projection of the mounting area 121 on the first side 11 overlaps with the bonding area 111 completely, the overall width of the circuit board body 10 may be reduced by 2 mm.

Further, as shown in FIGS. 1 and 2, the amount of bonding areas is plural, and the bonding areas are defined at intervals along one long side of the circuit board body 10. In this embodiment, each bonding area 111 is defined with a bonding mark, and the driving chips 21 of the display panel are correspondingly multiple to respectively correspond to each bonding area 111. The bonding area between the display screen 20 and the circuit board is larger and the bonding connection stability is improved. It may be appreciated that the interval between any two adjacent bonding areas 111 is not sufficient to mount the functional chip 13.

Further, as shown in FIGS. 1 and 2, the amount of mounting sites is plural, and the mounting sites are defined at intervals along the length direction of the mounting area 121. In this embodiment, the mounting area 121 extends along the length direction of the circuit board body 10, and a plurality of mounting sites are defined at intervals along the length direction of the mounting area 121 to reduce the area occupied by the mounting sites in the direction of the width of the circuit board body 10. A plurality of mounting sites are configured to mount a plurality of functional chips 13. In practical application, the mounting sites may preferably be defined with mounting marks. When mounting the functional chips 13, only the functional chips 13 need to be soldered to the sites defined with mounting marks, thereby simplifying the manufacturing process of circuit board components and improving the production efficiency.

Further, as shown in FIGS. 1 and 2, the circuit board assembly further includes a functional chip 13 mounted on the mounting site. In this embodiment, the function chip 13 is configured to provide controller, power or programming functions for the display panel to improve the function integration effect of the circuit board assembly.

Further, the functional chip 13 is soldered to the mounting site by a reflow soldering process. According to this embodiment, in the reflow soldering process, a functional chip 13 with solder is firstly attached to a circuit board body 10; then after being heat to a sufficiently high temperature, the air or nitrogen is blow to the circuit board body 10 with the functional chip 13 attached. After the solder on the functional chip 13 melts, the melted solder adheres to the circuit board body 10, so that the functional chip 13 is firmly soldered to the circuit board body 10. It is easy to control the temperature in the reflow soldering process. The reflow soldering process may also effectively avoid oxidation reaction, and make it convenient for intensively soldering, and is beneficial to reducing the processing cost. It can be understood that the bonding of the functional chip 13 on the second side 12 does not affect the first side 11, that is, even if the projection of the mounting area 121 on the first side 11 overlaps with the bonding area 111, the bonding area 111 on the back may not be affected by the bonding of the functional chip 13, that is, the driving chip 21 of the display panel may still be effectively bonded to the circuit board body 10 in the bonding area 111.

Further, the function chip 13 includes at least one selected from a group consisting of a timing control chip, a power chip, and a programmable gamma chip. In this embodiment, the timing control chip is configured to apply temporal control to the signal flow of the display panel, so that each functional module of the display panel may work in chronological order. A power chip is configured to provide stable voltage for the operation of each functional module of the display panel, so that each functional module may work effectively. A programmable gamma chip is configured to provide the data driving chip 21 of the display panel with the gamma voltage necessary for its operation so that the data driving chip 21 may work effectively. It can be understood that the timing control chip, the power chip and the programmable gamma chip may all be preferentially mounted on the mounting area 121 to improve the function integration effect of the circuit board assembly. The sequence and interval of the timing control chip, the power chip and the programmable gamma chip are not limited here, but only are required to be mounted on the mounting site.

The disclosure also provides a display panel including a circuit board assembly, the specific structure of the circuit board assembly refers to the above-mentioned embodiments. Since the display panel employs all the technical schemes of all the above-mentioned embodiments, it has at least all the technical effects brought about by the technical schemes of the above-mentioned embodiments and will not be described in detail here. The display panel also includes a display screen 20 and a data driving chip 21. One side of the data driving chip 21 is electrically connected with the display screen 20, and the other side of the data driving chip 21 is connected with the area 111 of the circuit board assembly via bonding.

The present disclosure also proposes a display device including a display panel, the specific structure of the display panel refers to the above-mentioned embodiments. Since this display device employs all the technical schemes of all the above-mentioned embodiments, it has at least all the technical effects brought about by the technical schemes of the above-mentioned embodiments and will not be described in detail here.

The above is only the preferred embodiment of the present disclosure and is not therefore limiting the scope of the patent disclosure. Any equivalent structural change made under the inventive concept of the present disclosure using the contents of the present disclosure specification and drawings, or directly/indirectly applied in other related technical fields, is included in the scope of the patent protection of the present disclosure.

What is claimed is:

1. A circuit board assembly, wherein the circuit board assembly comprises:
a circuit board body, comprising a first side surface and a second side surface, the first side surface faces away from the second side surface, the first side surface defines a bonding area, the second side surface defines a mounting area, and the mounting area defines a mounting site for mounting a functional chip.

2. The circuit board assembly of claim 1, wherein the projection of the mounting area on the first side at least partially overlaps with the bonding area.

3. The circuit board assembly according to claim 2, wherein the width of the overlap is 0 mm to 2 mm.

4. The circuit board assembly according to claim 1, wherein the amount of the bonding area is plural, and the plural bonding areas are defined along a long side of the circuit board body at intervals.

5. The circuit board assembly according to claim 1, wherein the amount of mounting site is plural, and the plurality of mounting sites are defined along the length direction of the mounting area at intervals.

6. The circuit board assembly of claim 1, wherein the circuit board assembly further comprises a functional chip mounted on the mounting site.

7. The circuit board assembly according to claim 6, wherein the functional chip is soldered to the mounting site.

8. The circuit board assembly of claim 6, wherein the functional chip comprises at least one selected from a group consisting of a timing control chip, a power chip, and a programmable gamma chip.

9. The circuit board assembly according to claim 1, wherein the bonding area defines a bonding mark for bonding a driving chip of the display panel to the circuit board.

10. The circuit board assembly according to claim 1, wherein the circuit board body is defined in a strip shape, and a long side of the circuit board body faces to one side of the display screen.

11. The circuit board assembly of claim 2, wherein the projection of the mounting area on the first side completely overlap with the bonding area.

12. The circuit board assembly of claim 4, wherein the spacing between any two adjacent bonding areas is smaller than the size of the functional chip.

13. The circuit board assembly of claim 5, wherein the mounting area extends along the length direction of the circuit board body.

14. The circuit board assembly according to claim 5, wherein the mounting site defines a mounting mark for mounting the functional chip.

15. The circuit board assembly according to claim 7, wherein the functional chip is soldered to the mounting site by a reflow soldering process.

16. The circuit board assembly of claim 8, wherein the functional chip comprises a timing control chip, a power chip, and a programmable gamma chip.

17. The circuit board assembly according to claim 2, wherein the circuit board assembly further comprises a functional chip mounted on the mounting site.

18. The circuit board assembly according to claim 3, wherein the circuit board assembly further comprises a functional chip mounted on the mounting site.

19. A display panel, comprising a circuit board assembly, wherein the circuit board assembly comprises: a circuit board body, comprising a first side and a second side, the first side facing away from the second side, the first side defining a bonding area, the second side defining a mounting area, the mounting area defining a mounting site for mounting a functional chip.

20. A display device, comprising a display panel, wherein the display panel comprises a circuit board assembly, the circuit board assembly comprises a circuit board body, the circuit board body comprises a first side and a second side, the first side facing away from the second side, the first side defining a bonding area, the second side defining a mounting area, the mounting area defining a mounting site for mounting a functional chip.
